(19) United States
(12) Patent Application Publication
(10) Pub. No.: US 2021/0407329 A1
(43) Pub. Date: Dec. 30, 2021

(54) FLEXIBLE DISPLAY PANEL

(71) Applicant: WUHAN CHINA STAR OPTOELECTRONICS SEMICONDUCTOR DISPLAY TECHNOLOGY CO., LTD., Wuhan (CN)

(72) Inventors: Quan HU, Wuhan (CN); Songshan LI, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 16/631,455

(22) PCT Filed: Nov. 5, 2019
(86) PCT No.: PCT/CN2019/115515

§ 371 Date: Jan. 16, 2020

(30) Foreign Application Priority Data
Aug. 15, 2019 (CN) 201910755257.0

(51) Int. Cl. G09F 9/30; H01L 51/52

(52) U.S. Cl. CPC G09F 9/301; H01L 2251/5338; H01L 51/52

(57) ABSTRACT

A flexible display panel is provided, which includes a flexible base and a flexible display screen body, and the flexible display screen body has a bending region. A stress buffer structure is disposed on a backside of the flexible base. The stress buffer structure includes a plurality of protruding sections. Grooves are disposed between the adjacent protruding sections and are extended along a length direction of the bending region.

### FIELD OF INVENTION

The present disclosure relates to the field of display technology, and particularly relates to a flexible display panel.

### BACKGROUND OF INVENTION

Active matrix organic light emitting diode (AMOLED) display panels are gradually becoming a new generation display technology due to their characteristics of high contrast, wide color gamut, low power consumption, foldabilities, etc. Comparing them to traditional light emitting diode (LED) display panels, the organic light emitting diode (OLED) display panels are easy to be flexible, which is key technology of crimpable and foldable products.

However, in the display industry, because stress in light emitting areas of an OLED is difficult to be released, cracks and fragmentation easily occur during a bending process of a base of a bottom of the OLED display panel.

The technical problem is that in the display industry, because stress in light emitting areas of an OLED is difficult to be released, cracks and fragmentation easily occur during a bending process of a base of a bottom of the OLED display panel.

### SUMMARY OF INVENTION

A flexible display panel includes a flexible base and a flexible display screen body located on the flexible base. The flexible display screen body has a bending region. A stress buffer structure is disposed on a backside of the flexible base, the stress buffer structure includes a plurality of protruding sections, and grooves are disposed between the adjacent protruding sections and are extended along a length direction of the bending region. Pitches between vertexes and bottom edges of the protruding sections range from 5 μm to 12 μm, and pitches between the vertexes of the protruding sections range from 5 μm to 15 μm.

Furthermore, longitudinal sections of the protruding sections are triangular shapes, and a longitudinal section of the stress buffer structure is a zigzag shape.

Furthermore, base angles of the protruding sections are greater than or equal to 30 degrees, and less than or equal to 120 degrees.

Furthermore, longitudinal sections of the protruding sections are square shapes, trapezoidal shapes, semi-elliptical shapes, or semi-circular shapes.

Furthermore, the bottom edges of the protruding sections are located between the flexible base and vertexes of the protruding sections.

Furthermore, the stress buffer structure and the flexible base are integrated in one piece.

Furthermore, the protruding sections include a plurality of convexities independent to each other, and the convexities of each of the protruding sections are arranged at intervals along the length direction of the bending region.

Furthermore, cross sections of the protruding sections are successive strip shapes, and the protruding sections are extended along the length direction of the bending region.

A flexible display panel includes a flexible base and a flexible display screen body, and the flexible display screen body has a bending region. A stress buffer structure is disposed on a backside of the flexible base. The stress buffer structure includes a plurality of protruding sections. Grooves are disposed between the adjacent protruding sections and are extended along a length direction of the bending region.

Furthermore, longitudinal sections of the protruding sections are triangular shapes, and a longitudinal section of the stress buffer structure is a zigzag shape.

Furthermore, base angles of the protruding sections are greater than or equal to 30 degrees, and less than or equal to 120 degrees.

Furthermore, longitudinal sections of the protruding sections are square shapes, trapezoidal shapes, semi-elliptical shapes, or semi-circular shapes.

Furthermore, the bottom edges of the protruding sections are located between the flexible base and vertexes of the protruding sections.

Furthermore, pitches between vertexes and bottom edges of the protruding sections range from 5 μm to 12 μm.

Furthermore, pitches between the vertexes of the protruding sections range from 5 μm to 15 μm.

Furthermore, the stress buffer structure and the flexible base are integrated in one piece.

Furthermore, the protruding sections include a plurality of convexities independent to each other, and the convexities of each of the protruding sections are arranged at intervals along the length direction of the bending region.

Furthermore, cross sections of the protruding sections are successive strip shapes, and the protruding sections are extended along the length direction of the bending region.

When the flexible display panel is dynamically bent along the bending region, great stress on the flexible base is released by the stress buffer structure to prevent from stress concentration occurring on the bending region, and to prevent from fragmentation and cracks occurring on the flexible base during bending, thereby yield of the flexible display panel being improved.

### DESCRIPTION OF DRAWINGS

In order to more clearly illustrate embodiments or the technical solutions of the present disclosure, the accompanying figures of the present disclosure required for illustrating embodiments or the technical solutions of the present disclosure will be described in brief. Obviously, the accompanying figures described below are only part of the embodiments of the present disclosure, from which those skilled in the art can derive further figures without making any inventive efforts.

FIG. 1 is a schematic diagram of a flexible display panel of the present disclosure being in an expanded state.

FIG. 2 is a schematic diagram of a flexible display panel of the present disclosure having one bending region and being in a bending state.

FIG. 3 is a schematic diagram of a flexible display panel of the present disclosure having two bending regions and being in the bending state.

FIG. 4 is a structural schematic diagram of protruding sections of an embodiment of the present disclosure.

FIG. 5 is a structural schematic diagram of protruding sections of another embodiment of the present disclosure.

FIG. 6 is a structural schematic diagram of a flexible display panel of a second embodiment of the present disclosure.

FIG. 7 is a structural schematic diagram of a flexible display panel of a third embodiment of the present disclosure.

FIG. 8 is a structural schematic diagram of a flexible display panel of a fourth embodiment of the present disclosure.

### DETAILED DESCRIPTION OF PREFERRED EMBODIMENTS

The descriptions of embodiments below refer to accompanying drawings in order to illustrate certain embodiments which the present disclosure can implement. The directional terms of which the present disclosure mentions, for example, “top”, “bottom”, “upper, “lower”, “front”, “rear”, “left”, “right”, “inside”, “outside”, “side”, etc., are only refer to directions of the accompanying figures. Therefore, the used directional terms are for illustrating and understanding the present disclosure, but not for limiting the present disclosure. In the figures, units with similar structures are indicated by the same reference numerals.

The present disclosure aims at current organic light emitting diode (OLED) display panels having the technical problem of cracks and fragmentation easily occurring during a bending process of a base of a bottom of the OLED display panel. The present disclosure can solve the problem mentioned above.

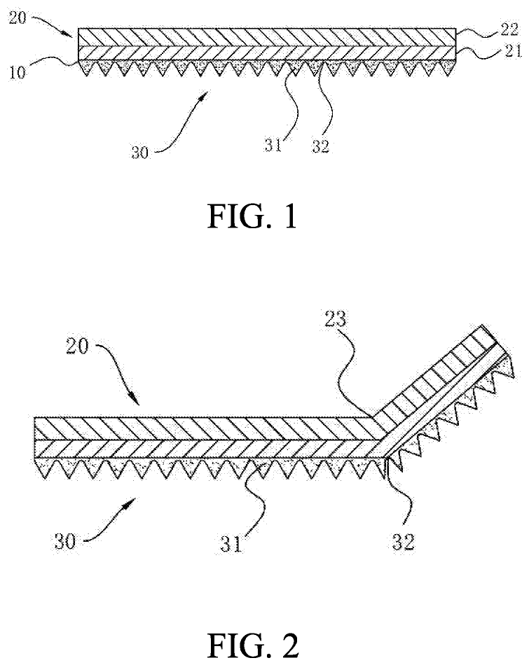

As illustrated in FIG. 1 and FIG. 2, a flexible display panel includes a flexible base 10 and a flexible display screen body 20 located on the flexible base 10. The flexible display screen body 20 includes a thin film transistor device layer 21 and an organic light emitting layer 22 disposed on the thin film transistor device layer 21.

Furthermore, the flexible display screen body 20 has a display region. A bending region 23 is disposed on the display region of the flexible display screen body 20. The flexible base 10 and the flexible display screen body 20 are rotated along the bending region 23 to be bent or to be unfolded.

Furthermore, a stress buffer structure 30 is disposed on a backside of the flexible base 10. The stress buffer structure 30 includes a plurality of protruding sections 31. Grooves 32 are disposed between the adjacent protruding sections 31 and are extended along a length direction of the bending region 23.

When the flexible display panel is dynamically bent along the bending region 23, great stress on the flexible base 10 can be released by the stress buffer structure 30 to prevent from stress concentration occurring on the bending region 30, thereby preventing from fragmentation and cracks occurring on the flexible base 10 during bending, and yield of the flexible display panel is improved.

In an embodiment, an orthogonal projection of the grooves 32 on the flexible base 10 includes and accommodates an orthogonal projection of the bending region 23 on the flexible base 10.

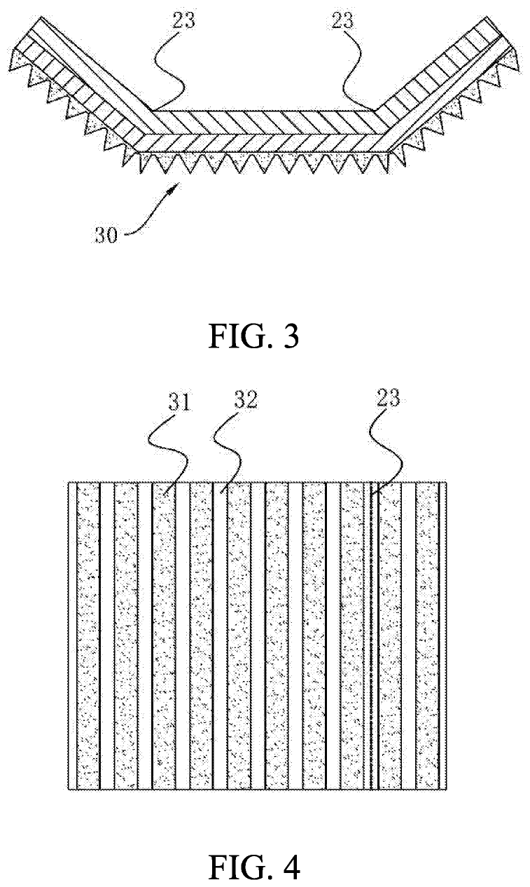

It should be noted that FIG. 2 only shows a situation of the flexible display screen body 20 having one bending region 23. In specific implementation, as illustrated in FIG. 3, the flexible display screen body 20 may also have two or more independent bending regions 23.

In an embodiment, as illustrated in FIG. 4, the protruding sections 31 include a plurality of convexities 311 independent to each other, and the convexities 311 of each of the protruding sections 31 are arranged at intervals along the length direction of the bending region 23.

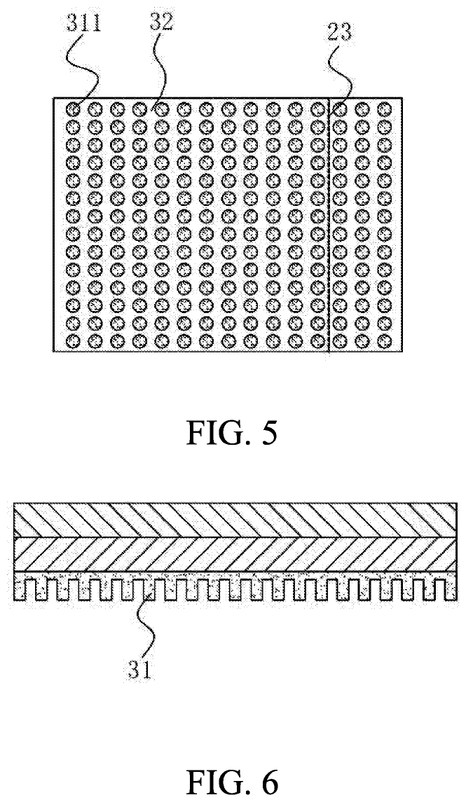

In another embodiment, as illustrated in FIG. 5, cross sections of the protruding sections 31 are successive strip shapes, and the protruding sections 31 are extended along the length direction of the bending region 23.

In the first implement method, longitudinal sections of the protruding sections 31 are triangular shapes, and a longitudinal section of the stress buffer structure 30 is a zigzag shape.

Furthermore, the longitudinal sections of the protruding sections 31 are isosceles triangles, and base angles of the protruding sections 31 are greater than or equal to 30 degrees, and less than or equal to 120 degrees, thereby making the stress release more completely when the flexible display panel is bent.

In the second implement method, as illustrated in FIG. 6, longitudinal sections of the protruding sections 31 are square shapes.

Furthermore, the longitudinal sections of the protruding sections 31 are rectangular shapes.

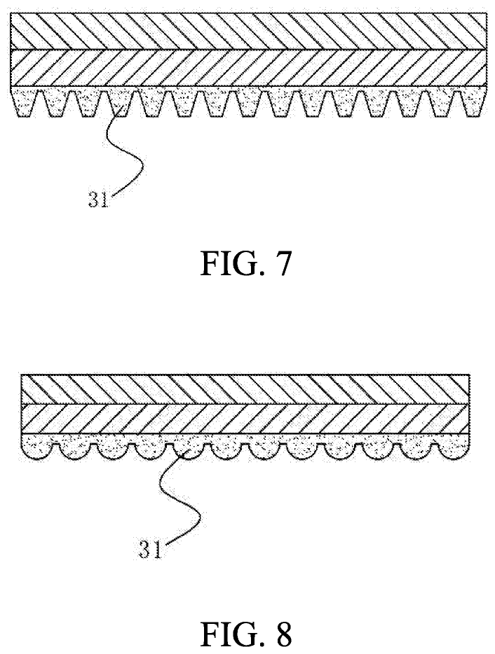

In the third implement method, as illustrated in FIG. 7, the longitudinal sections of the protruding sections 31 are trapezoidal shapes.

Furthermore, the longitudinal sections of the protruding sections 31 are inverted trapezoidal shapes.

In the fourth implement method, as illustrated in FIG. 8, the longitudinal sections of the protruding sections 31 are semi-circular shapes.

It should be noted, in actual implementation, the longitudinal sections of the protruding sections 31 may also be other shapes, such as large semi-circular shapes, ellipses or large semi-ellipses, etc., which are not enumerated here.

Specifically, the bottom edges of the protruding sections 31 are located between the flexible base 10 and vertexes of the protruding sections 31, that is, the protruding sections 31 are convex structures, and the vertexes of the protruding sections 31 are disposed toward a direction away from the flexible base 10.

Specifically, pitches between the vertexes of the protruding sections 31 and the bottom edges range from 5 μm to 12 μm, and pitches between the vertexes of the adjacent protruding sections 31 range from 5 μm to 15 μm.

In an embodiment, pitches between the vertexes of the protruding sections 31 and the bottom edges is 10 μm, and pitches between the vertexes of the adjacent protruding sections 31 is 8 μm.

Specifically, the stress buffer structure 30 and the flexible base 10 are integrated in one piece, thereby making the stress can be released more completely when the flexible display panel is bent, and meanwhile preventing the protruding sections 31 being separated from the flexible base 10.

In an embodiment, a preparation material of the flexible base 10 is polyimide, and in processes of manufacturing the flexible display panel, forming a thin film transistor device layer 21 on the flexible base 10, evaporating organic light emitting material on the thin film transistor device layer 21, after forming the organic light emitting layer 22, using imprint technology to imprint on a back surface of the flexible base 10 to form the stress buffer structure 30 integrated in one piece with the flexible base 10.

In a specific implement method, the preparation material of the flexible base 10 may be other material, such as flexible plastic or flexible glass, etc., which are not enumerated here.

The beneficial effect of the present disclosure is that when the flexible display panel is dynamically bent along the bending region 23, great stress on the flexible base 10 is released by the stress buffer structure 30 to prevent from stress concentration occurring on the bending region 23, and to prevent from fragmentation and cracks occurring on the flexible base 10 during bending, thereby yield of the flexible display panel being improved.

In summary, although the present disclosure has disclosed the preferred embodiments as above, however the above-mentioned preferred embodiments are not to limit to the present disclosure. A person skilled in the art can make any change and modification, therefore the scope of protection of the present disclosure is subject to the scope defined by the claims.

What is claimed is:

1. A flexible display panel, wherein the flexible display panel comprises a flexible base and a flexible display screen body located on the flexible base, and the flexible display screen body has a bending region; wherein a stress buffer structure is disposed on a backside of the flexible base, the stress buffer structure comprises a plurality of protruding sections, grooves are disposed between the adjacent protruding sections and are extended along a length direction of the bending region, pitches between vertexes and bottom edges of the protruding sections range from 5 μm to 12 μm, and pitches between the vertexes of the protruding sections range from 5 μm to 15 μm.

2. The flexible display panel as claimed in claim 1, wherein longitudinal sections of the protruding sections are triangular shapes, and a longitudinal section of the stress buffer structure is a zigzag shape.

3. The flexible display panel as claimed in claim 2, wherein base angles of the protruding sections are greater than or equal to 30 degrees, and less than or equal to 120 degrees.

4. The display panel as claimed in claim 1, wherein longitudinal sections of the protruding sections are square shapes, trapezoidal shapes, semi-elliptical shapes, or semi-circular shapes.

5. The flexible display panel as claimed in claim 3, wherein the bottom edges of the protruding sections are located between the flexible base and vertexes of the protruding sections.

6. The flexible display panel as claimed in claim 1, wherein the stress buffer structure and the flexible base are integrated in one piece.

7. The flexible display panel as claimed in claim 1, wherein the protruding sections comprise a plurality of convexities independent to each other, and the convexities of each of the protruding sections are arranged at intervals along the length direction of the bending region.

8. The flexible display panel as claimed in claim 1, wherein cross sections of the protruding sections are successive strip shapes, and the protruding sections are extended along the length direction of the bending region.

9. A flexible display panel, wherein the flexible display panel comprises a flexible base and a flexible display screen body, and the flexible display screen body has a bending region; wherein a stress buffer structure is disposed on a backside of the flexible base, the stress buffer structure comprises a plurality of protruding sections, grooves are disposed between the adjacent protruding sections and are extended along a length direction of the bending region.

10. The flexible display panel as claimed in claim 9, wherein longitudinal sections of the protruding sections are triangular shapes, and a longitudinal section of the stress buffer structure is a zigzag shape.

11. The flexible display panel as claimed in claim 10, wherein base angles of the protruding sections are greater than or equal to 30 degrees, and less than or equal to 120 degrees.

12. The display panel as claimed in claim 9, wherein longitudinal sections of the protruding sections are square shapes, trapezoidal shapes, semi-elliptical shapes, or semi-circular shapes.

13. The flexible display panel as claimed in claim 11, wherein the bottom edges of the protruding sections are located between the flexible base and vertexes of the protruding sections.

14. The flexible display panel as claimed in claim 9, wherein pitches between vertexes and bottom edges of the protruding sections range from 5 μm to 12 μm.

15. The flexible display panel as claimed in claim 9, wherein pitches between the vertexes of the protruding sections range from 5 μm to 15 μm.

16. The flexible display panel as claimed in claim 9, wherein the stress buffer structure and the flexible base are integrated in one piece.

17. The flexible display panel as claimed in claim 9, wherein the protruding sections comprise a plurality of convexities independent to each other, and the convexities of each of the protruding sections are arranged at intervals along the length direction of the bending region.

18. The flexible display panel as claimed in claim 9, wherein cross sections of the protruding sections are successive strip shapes, and the protruding sections are extended along the length direction of the bending region.
